(19) United States
(12) Patent Application Publication
(10) Pub. No.: US 2024/0212893 A1
(43) Pub. Date: Jun. 27, 2024

(54) SELECTIVE THIN FILM RESISTOR AND METHODS FOR MAKING SAME

(71) Applicant: Greensource Fabrication, Chester, CT (US)

(72) Inventors: Mark CHASSE, Chester, CT (US); Andreas SCHILLOFF, Chester, CT (US); Michael GLEASON, Chester, CT (US); Alex STEPINSKI, Chester, CT (US)

(73) Assignee: Greensource Fabrication, Chester, CT (US)

(21) Appl. No.: 18/392,584

(22) Filed: Dec. 21, 2023

Related U.S. Application Data
(60) Provisional application No. 63/434,836, filed on Dec. 22, 2022.

(51) Int. Cl. H01C 17/075; C25D 3/38; C25D 5/02; G03F 7/00; H01C 7/00

(52) U.S. Cl. CPC H01C 17/075; C25D 3/38; C25D 5/022; G03F 7/0035; H01C 7/006

(57) ABSTRACT

The disclosure includes methods for making selective thin film resistors as well thin film resistors that comprise a dielectric core having a thin film resistor material located between copper conductors but where there is no thin film resistor material located under the copper conductors.

### CROSS REFERENCE TO RELATED APPLICATIONS

This application claims priority to U.S. Provisional Application No. 63/434,836, filed on Dec. 22, 2022, the contents of which are incorporated herein by reference in their entirety.

### BACKGROUND

Resistors are standard components in many semiconductor integrated circuits. For example, the resistor is typically used to control respective resistances of other electronic components of an integrated circuit, which can be a radio frequency (RF) circuit (e.g., an oscillator, phase-shift network, filter, converter, etc.), a memory (e.g., a dynamic random access memory (DRAM), a static random access memory (SRAM), etc.) circuit, and any of a variety of analog/mixed-signal circuits. Many integrated circuit devices incorporate thin film resistors (TFRs), which provide various advantages over other types of resistors. For example, TFRs may be highly accurate, and may be finely tuned to provide a very precise resistance value. As another example, TFRs typically have smaller parasitic components which provides advantageous high frequency behavior. In addition, TFRs typically have a low temperature coefficient of resistance (TCR), e.g., after a suitable annealing process to “tune” the TCR to a customer specified near-zero value, which may provide stable operation over a wide range of operating temperatures. However there remains a need for more efficient and accurate thin film resistors.

### SUMMARY OF THE DISCLOSURE

Embodiments of the disclosure include methods for making selective thin film resistor as well thin film resistors that comprise a dielectric core having a thin film resistor material located between copper conductors but where there is no thin film resistor material located under the copper conductors.

### BRIEF DESCRIPTION OF THE DRAWINGS

FIG. 1 provides figures of related art of thin film resistors (TFRs). There is often a copper layer, then a thin film resistor layer on a core material (i.e. a dielectric material), followed by another thin film resistor layer and finally another copper layer.

FIG. 2A and FIG. 2B show the comparison of non-selective and selective thin film resistor circuitization. FIG. 2A shows traditional circuitization using TFRs, which is called “non selective” as the film resistor material is located under the copper material as opposed to “selective” circuitization, which shows that the thin film resistor material (TFRM) is not under the copper material (which is shown in FIG. 2B), but instead is located on select desired areas on the core. FIG. 2B illustrates the selective TFR of the present disclosure, illustrating that it has the thin film resistor material (3) located only on desired areas of the core material (2) and not located under the copper film (4).

FIG. 3A shows the initial build up step. A layer of thin film resistor material (TFRM) (3) and copper foil (4a) can be supplied by a supplier and then bonded to a core (HF dielectric material) (2). Alternatively the full build up can be supplied by the laminate supplier. Or A layer of thin film resistor material (TFRM) (3) can be applied to a core (HF dielectric material) (2). Thereafter a first copper foil layer (4a) is applied on top of the TERM (3) using known methods.

FIG. 3B shows the copper etch down step. The first copper foil layer (4a) located on top of the thin film resistor layer may be etched to produce a first thin layer of copper (4b), since thinner copper layer improves the feature resolution. Alternatively, a thinner starting copper foil layer can be used to achieve a similar result in lieu of etching down the starting copper foil layer.

FIG. 3C shows the lamination of a photo-imageable resist material (4c).

FIG. 3D shows the next step. The photoresist material is exposed over the desired thin film resistor area (5). The exposed area is polymerized and therefore will not develop off.

FIG. 4 shows that the unexposed photoresist material has been developed off. This leaves the exposed resist material (5b) in the desired location on top of the first thin copper layer (4b), which is on top of the thin film resistor material (3). The exposed resist material (5b) covers the thin film resistor at desired areas and this is the beginning of the process for defining the Selective Thin Film Resistor.

FIG. 5 shows the resulting structure after the etchant has removed areas of the first thin copper layer (4b) and the thin film resistor material TFRM (3) that were not protected by the exposed resist material (5b), leaving only a “sandwich” (15) comprising a layer of TFRM (3), the first thin copper layer (4b) and exposed resist material (5b) located on top of the core (2).

FIG. 6 shows the resulting TFR structure after the exposed resist material (5b) has been stripped from the sandwich. This figure shows that the TFRM has been removed from areas except that which is located under the copper layer, thus leaving a sandwich (16) comprising a layer of TFRM (3) and the first thin copper layer (4b). Removing the thin film resistor layer that was applied to the core (except for the TERM in the sandwich (16)), overcomes the challenge of adhering follow-on metal applications (“metallization steps”).

FIG. 7 shows the application of a thin layer of seed copper (6) in preparation for Semi Additive Plating (SAP). A thin layer of seed copper (6) is applied over the core and the sandwich (16) using methods and materials know in the art.

FIG. 8 shows the application of a second imageable resist material layer (7) as a step to prepare for Semi Additive Plating (SAP).

FIG. 9 shows the second imageable resist material exposed (9) to mask the seed copper layer (6) and the sandwich (16) (the metallized bussing layer) prior to developing in order to open up the resistor feature (16) and associated connectors. Exposure is based on a UV light source and can be direct image technology or photolithography.

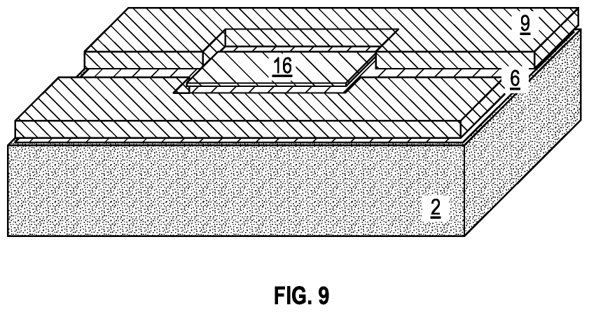

FIG. 10 shows exposed second imageable resist material layer (9) is developed in preparation for Semi Additive Plating (SAP). Only the unexposed second imageable resist material layer will be developed off.

FIG. 11 shows circuit build up using SAP pattern plating. Electrolytic copper is used to build up the circuitry. An electrolytic copper layer (8) is added in desired locations (using known deposition and lithographic methods), while the exposed second imageable resist material layer (9) is still present.

FIG. 12 shows the removal of exposed second imageable resist material layer in preparation for circuit definition. The exposed second imageable resist material layer (9) is stripped using NaOH or other chemistry prior to differential etching.

FIG. 13 shows differential etch for feature definition. The seed copper (6) has been removed to define a circuit.

FIG. 14 shows that a third photo-imageable resist material layer (11) has been applied.

FIG. 15 shows exposure of the third photo-imageable resist material layer (11) facilitates high resolution resistor definition.

FIG. 16 shows the development of the resist material and the selective copper etching steps to create the resistor. The third photo-imageable resist material layer (11) is developed to reveal the copper (17) below the third photo-imageable resist material layer (11). The copper below (17) is then etched away to reveal the Selective Thin Film Resistor (20). The remaining third photo-imageable resist layer (11) is stripped away using NaOH or other chemistry.

FIG. 17 shows the selective thin film resistor.

### DETAILED DESCRIPTION OF THE DISCLOSURE

Embodiments of the disclosure provide a method of manufacturing a selective thin film resistor (“STFR”) that has the thin film resistor material (“TFRM”) placed only on selective areas on a core as opposed to having the TERM present over the entire core and under copper conductors. In other words the TERM is not present under the copper film.

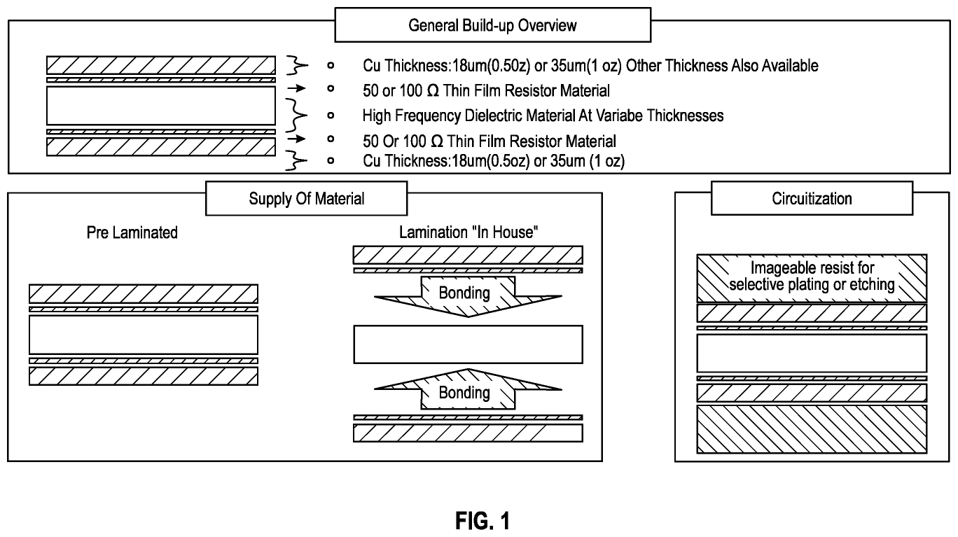

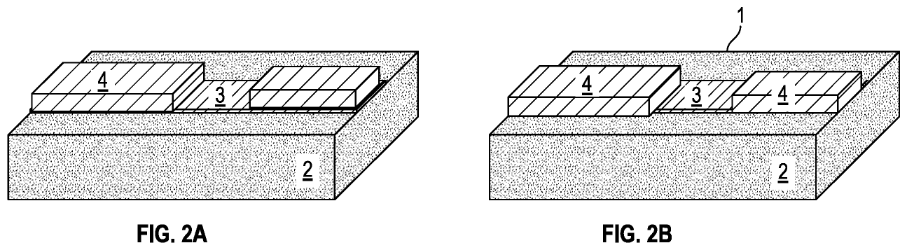

FIG. 1 illustrates a general overview of the buildup of a thin film resistor (TFR). As shown, the general build-p incudes a top layer of copper having a certain thickness, which may be for example 18 μm, 35 μm, or another thickness. Under the top copper layer is a TFRM, which as a predetermined resistance. Under the TERM is a high frequency (HF) dielectric material, which may be provided at variable thicknesses. Under this layer is another TFRM layer, and then a bottom copper layer. As shown in FIG. 1, the layers may be pre-laminated, or may be laminated by applying a bonding material between at least the TERM and dielectric layers. To complete circuitization, an imageable resist material for selective plating or etching is applied to the copper layers. FIG. 2A shows a typical thin film resistor structure, which has a TFRM (3) located on the core (2) and also located under the adjacent copper film (4). FIG. 2B shows a STFR (1) where the TERM (3) is located on the core (2) but it is not under adjacent areas of the copper film (4). Only having the TERM in desired positions on the core and not present under the copper film, the STFR exhibits less “skin effect” and thus has a lower signal loss than traditional thin film resistors (TFR).

Typically TFRs have core materials that are high frequency dielectric (often referred to herein as HF dielectric core) and are commonly polytetrafluoroethylene (PTFE) or mixtures containing PTFE. TFRMs are usually alloys of NiCr (nickel-chromium) “nichrome” or tantalum nitride (TAN).

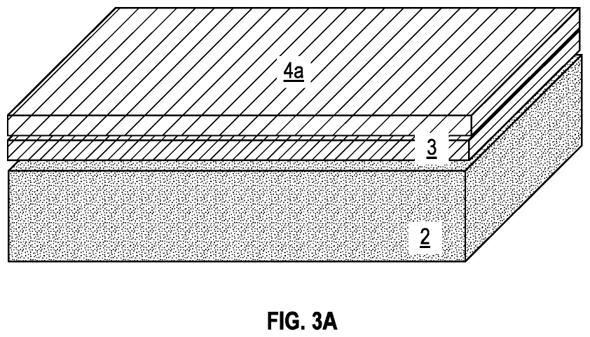

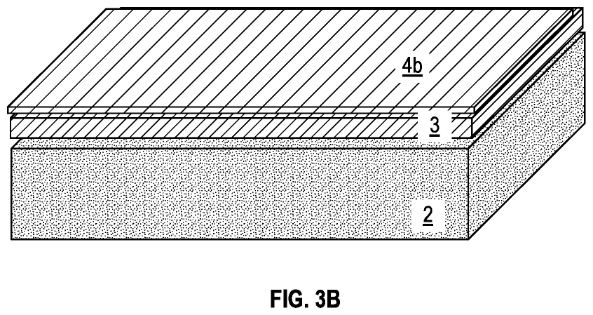

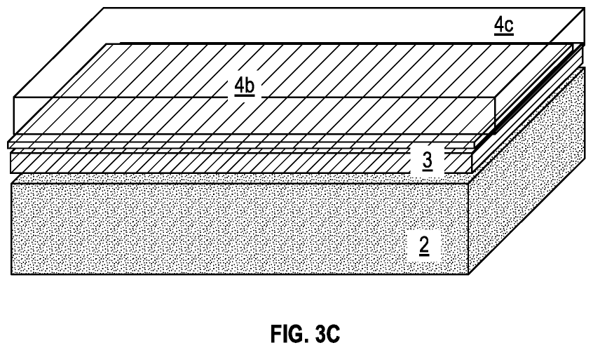

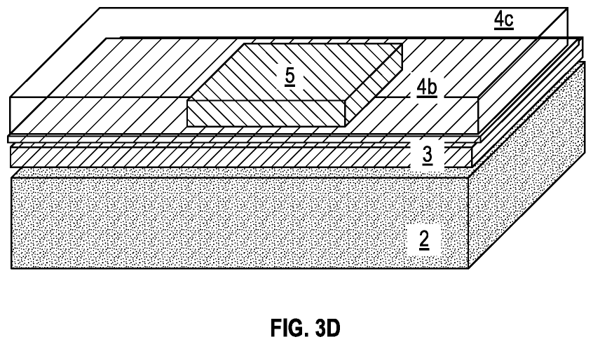

FIG. 3A shows an initial build up in a process for making a Selective Thin Film Resistor (STFR). A first copper foil layer (4a) is applied on top of a thin film resistor material (3), which has been applied to an HF dielectric core (2).

FIG. 3B shows a copper etch down step. Here the first copper foil layer (4) that was previously applied is etched so as to render the layer thinner, resulting in a first thin copper layer (4b). For example, the layer may be etched down from about 18 μm to between 2-4 μm using an acid etch. Typical acid etch materials maybe used in this etching step. Alternatively, a thinner starting copper foil layer can be used to achieve a similar result in lieu of etching down the starting copper foil layer. A thinner copper layer improves feature resolution when etched.

FIG. 3C shows the lamination step. A photo imageable resist material (4c) is applied to the top of the first thin copper layer (4b).

FIG. 3D shows the next step, in which the photo imageable resist material (4c) is exposed over the desired thin film resistor area (5). This desired thin film resistor area (5) that is exposed becomes polymerized and therefore will not develop off. Exposure is based on a UV light source and can be direct image technology or photo-lithography can be used.

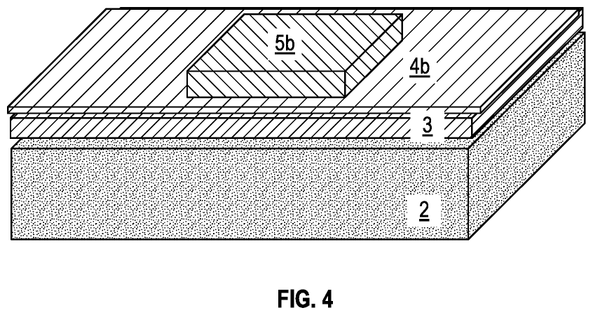

FIG. 4 shows that the unexposed photo imageable resist material is then developed off. Known developing solutions can be used. This leaves the exposed resist material (5b) in the desired location on top of first thin copper layer (4b), which is on top of the thin film resistor material (3). The exposed resist material (5b) covers the area that will become the desired thin film resistor and this is the beginning of the process for defining the Selective Thin Film Resistor.

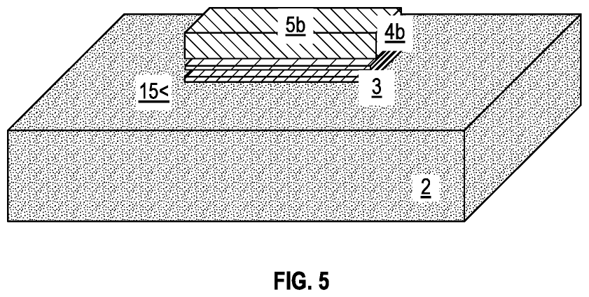

The resist material is any known and useful material that “protects” a copper film from an acid etchant that will be used to remove desired areas of the copper film and the thin film resistor material (TFRM) (3) not protected by the resist material. Known materials can be used to remove the copper layer that is not protected by the resist material. Typically, a slightly alkaline etching agent is applied to remove the copper film not protected by the resist material. Thereafter the TFRM (3) not protected by the resist material is removed using materials and processes applicable to the removal of TFRM. FIG. 5 shows the resulting product. It shows a “sandwich” (15) that remains after the etching steps discussed above, which comprises a layer of TFRM (3), the first thin copper layer (4b) and exposed resist material (5b) located on the core (2).

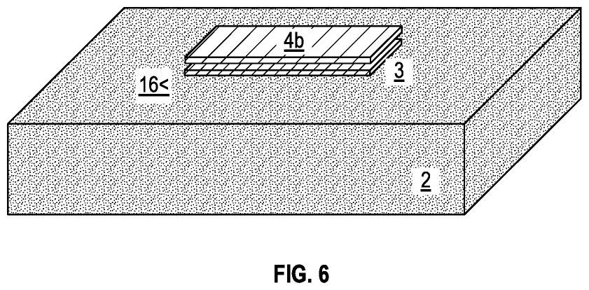

The next step is to remove the exposed resist material (5b). NaOH or other chemistry can be used to strip the exposed resist material (5b). The resulting structure is shown in FIG. 6. FIG. 6 shows the resulting product after the exposed resist material (5b) has been removed, thus leaving the sandwich (16) comprising a layer of TERM (3) and the first thin copper layer (4b). Removing the thin film resistor material that was deposited on the core (2) (except for desired areas—such as the TERM in the sandwich (16)), overcomes the challenge of adhering follow-on metal applications (“metallization steps”). For example, high frequency dielectrics present a challenge for the adhesion of the follow-on metallization steps. Removing the thin film resistor layer overcomes this.

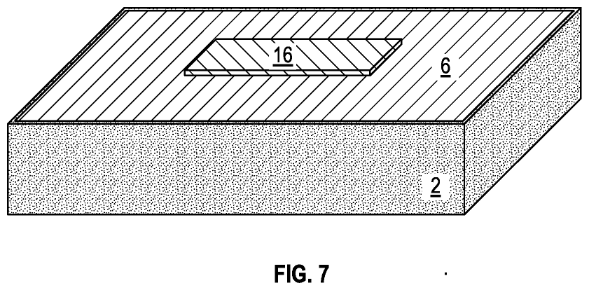

The next step in the process of making a Selective Thin Film Resistor (“STFR”), involves applying a thin layer of seed copper (6) over the sandwich (16) as well as over the core material (2), using know methods of copper deposition, as shown in FIG. 7. This application of a low build electroless copper metallization step allows high-definition and dense circuitry.

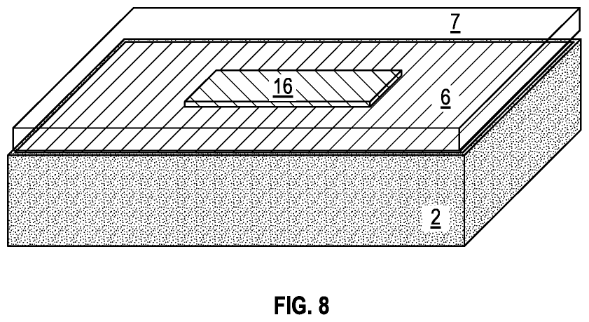

A second imageable resist material layer (7) is then applied in desired locations. As shown in FIG. 8, the second imageable resist layer (7) is placed over the sandwich (16) and the seed copper layer (6). The second imageable resist material layer (7) may be applied using a cut sheet laminator.

The second imageable resist material layer (7) is exposed to produce an exposed second imageable resist layer (9)—which is used to protect the sandwich (16) and the seed copper (6) that will not be reinforced as a etch protection by acid copper plating. That is, the second imageable resist material layer is selective exposed in certain areas to produce an exposed second imageable resists layer (9) to protect the resistor area and seed copper. Exposure is based on a UV light source and can be direct image technology or photo lithography methods.

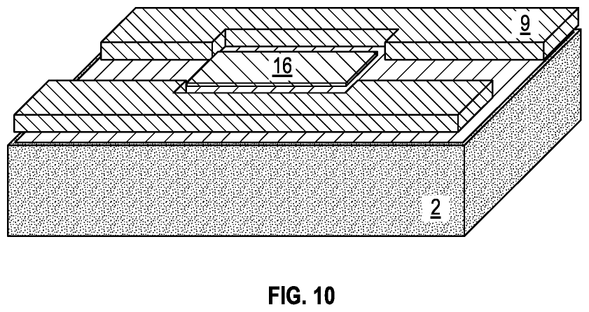

FIG. 10 shows the exposed second imageable resist material layer (9) is developed in preparation for Semi Additive Plating (SAP). Known imageable resist layer materials, liquid or dry, can be used along with known developing processes. Only the unexposed resist will develop off.

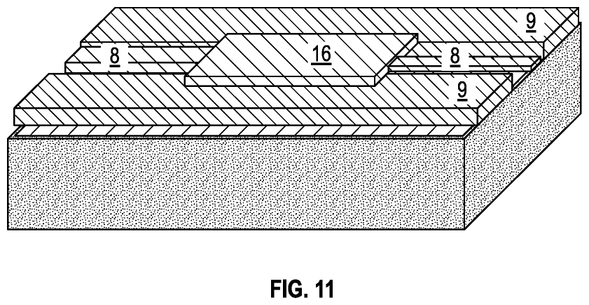

FIG. 11 shows circuit build up using SAP pattern plating. Electrolytic copper is used to build up the circuitry. An electrolytic copper layer (8) is added in desired locations (using known deposition and lithographic methods), while the exposed second imageable resist material layer (9) is still present.

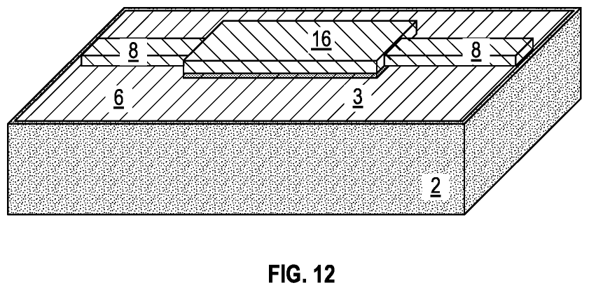

FIG. 12 shows the removal of the exposed second imageable resist material layer in preparation for circuit definition. The exposed second imageable resist layer material (9) is stripped using NaOH or other chemistry prior to differential etching.

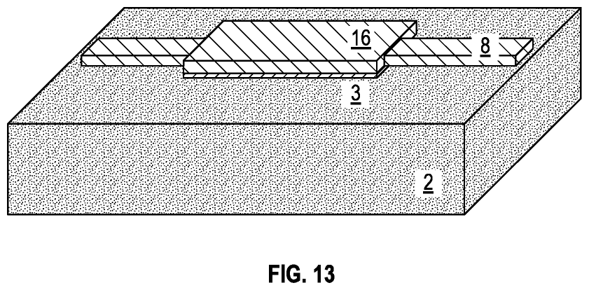

FIG. 13 shows the differential etch step used for feature definition. The seed copper (6) is removed to define a circuit.

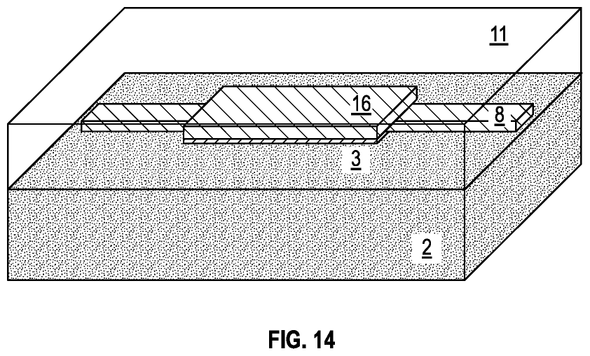

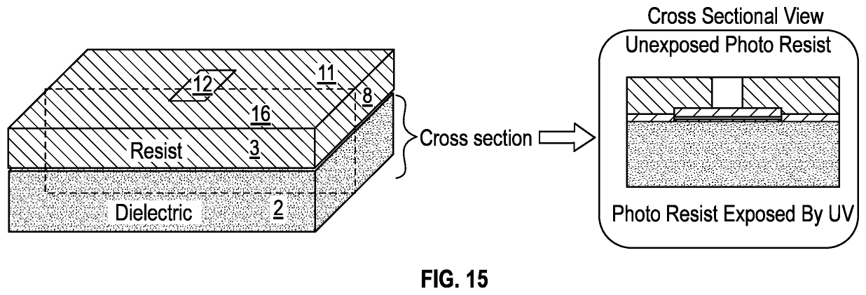

Next, a third photo-imageable resist material layer (11) is applied, as shown in FIG. 14. As shown in FIG. 15, the third photo-imageable resist material layer (11) is exposed to facilitate high resolution resistor definition. Exposure is based on a UV light source and can be direct image technology or photo lithography. A desired section is masked in order to provide an unexposed area of a third photo-imageable resist material layer (12), as shown in FIG. 15.

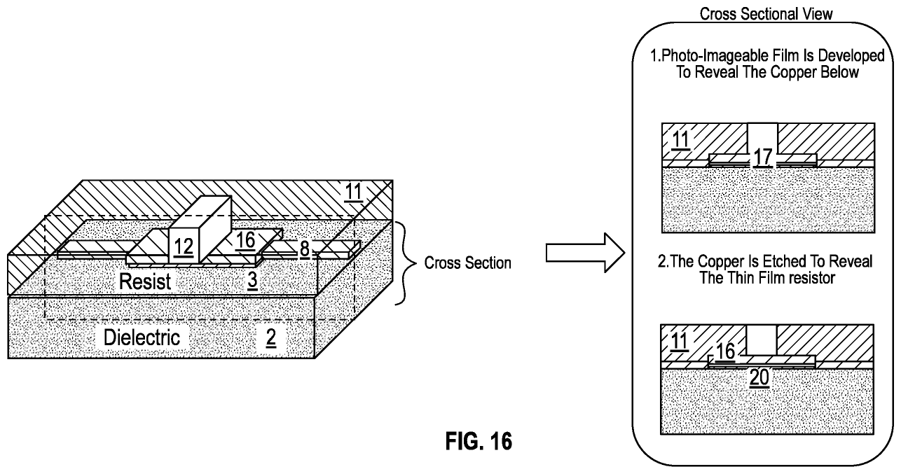

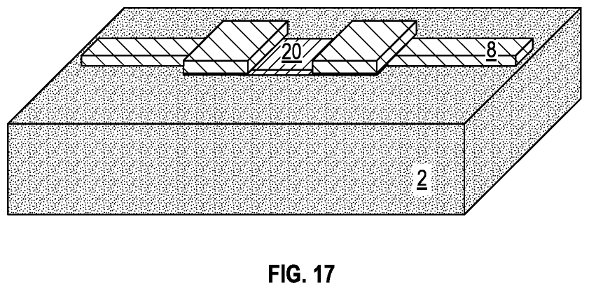

FIG. 16 shows the development of resist material and selective copper etching steps to create the resistor. The third photo-imageable resist material layer (11) is developed to reveal the copper (17) below the third photo-imageable resist material layer (11). The copper below (17) is then etched away to reveal the Selective Thin Film Resistor (20). The remaining third photo-imageable resist layer (11) is stripped away using NaOH or other chemistry, as shown in FIG. 17, which illustrates the resulting Selective Thin Film Resistor (20) between copper conductors. Notably, there is no thin film resistor material located under the copper conductors.

1. A method of making a selective thin film resistor, the method comprising:
a) providing a substrate comprising a high frequency dielectric material core having a layer of thin film resistor material (TFRM) and a first copper foil layer on top of the thin film resistor material;
b) etching down the first copper foil layer located on top of the thin film resistor layer to produce a first thin layer of copper;
c) laminating the first thin layer of copper with a first photo-imageable resist material;
d) in desired locations, exposing the first photo-imageable resist material in an area that corresponds to the area where the selective thin film resistor will be located;
e) developing off unexposed areas of the first photo-imageable resist material;
f) removing with an etchant, areas of the first thin layer of copper and thin film resistor material that are not located under the exposed first photo-imageable resist material;
g) stripping away the exposed area of the first photo-imageable resist material layer to leave a “sandwich” on the high frequency dielectric material core, wherein the “sandwich” comprises the thin film resistor layer and the first thin layer of copper;
h) applying a thin layer of seed copper over the sandwich and the core;
i) applying a second imageable resist material layer on top of the thin layer of seed copper;
j) exposing the second imageable resist material layer in desired areas;
k) developing the second imageable resist material layer to remove unexposed portions of the second imageable resist material layer;
l) adding an electrolytic copper layer to desired locations while the exposed second imageable resist material layer is still present;
m) removing the exposed second imageable resist material layer;
n) removing desired surrounding areas of the thin seed copper layer located on the high frequency dielectric material core;
o) applying a third imageable resist material layer;
p) exposing portions of the third imageable resist material layer;
q) developing unexposed portions of the third imageable resist material layer;
r) etching the copper layer that was below the developed unexposed portions of the third imageable resist material layer to reveal the thin film resistor material;
s) removal of the exposed portions of the third imageable resist material layer to create a selective thin film resistor located between copper conductors.

2. A thin film resistor prepared by the method of claim 1.

3. A thin film resistor wherein thin film resistor material is located between copper conductors, wherein there is no thin film resistor material located under the copper conductors.
